(19) United States
(12) Patent Application Publication
(10) Pub. No.: US 2025/0383391 A1
(43) Pub. Date: Dec. 18, 2025

(54) SEQUENCING WIRE ASSEMBLY FOR AUTONOMOUS ROUTING

(71) Applicant: The Boeing Company, Arlington, VA (US)

(72) Inventors: Karthik Dharmalingam, Bothell, WA (US); Aldo Mario Barletta, Lake Stevens, WA (US); Robert W. Grube, Edmonds, WA (US); Shawn David Mohlman, Mill Creek, WA (US)

(21) Appl. No.: 18/742,435

(22) Filed: Jun. 13, 2024

(51) Int. Cl. G01R 31/00

(52) U.S. Cl. CPC G01R 31/008

(57) ABSTRACT

Sequencing wire assembly for autonomous routing is described. Sequencing includes defining a weighted directed conflict graph representing a plurality of wires to be routed in a raceway includes a plurality of nodes defined by the plurality of wires and a plurality of edges defined by a set of routing precedents among the plurality of wires where a subsequent wire that is to be routed across a precedent wire within the raceway yields routing precedence to the precedent wire with regard to sequencing wire assembly denoted by one of the plurality of edges between the precedent wire and the subsequent wire that is directed from the precedent wire to the subsequent wire, increments an integer value of deg out=1 with regard to the precedent wire and increments an integer value deg in=1 with regard to the subsequent wire.

### BACKGROUND INFORMATION

### 1. Field

The present disclosure relates generally to sequencing wire assembly for autonomous routing apparatus and methodologies, and more specifically to sequencing wire assembly for autonomous routing for raceway modules and associated methodologies.

### 2. Background

Aerospace, automotive, submersible and robotics are some demanding applications for electrical design and implementation. These applications include interconnected elements such as passive components, active components, control units, sensors, transducers, and actuators. These elements need to be connected to power circuits as well as to control circuits. Consequently, the wiring for these elements can be complicated. The wiring can be designed and implemented with grouping in bundles or cables and/or by routing through conduits and raceways.

In the past, conduits and raceways conveying wires were assembled by hand. Individual wires, bundles, and cables were fed through conduits and/or laid along raceways manually. The order of operations was typically as deemed appropriate by the designer and/or the assembler. Raceways grant easier access.

Since then, automating wire routing along raceways using machinery helps to reduce takt times while meeting design constraints. Approaches to automating the routing task recognized the need to determine wire paths and branch point locations within the available space of the conduit or raceway.

However, a significant drawback to this previous automated approach is that the machinery is typically limited to a point along the raceway and no further due to branch points where wires cross to exit the raceway and consequently constrain the machinery from moving beyond, or even to, the branch point. Consequently, sequencing the routing process is very important to optimize automation.

Therefore, it would be desirable to have a tool for sequencing wire assembly for autonomous routing, as well as methods of using that tool that take into account at least some of the issues discussed above, as well as other possible issues.

### SUMMARY

There is a need for the following embodiments of the present disclosure. Of course, the present disclosure is not limited to these embodiments.

An embodiment of the present disclosure can include autonomously routing wires in aircraft electrical system or raceway in an optimized laydown sequence, ensuring the maximum number of wires can be routed given wire grouping and breakout constraints. Embodiments of this disclosure can include an algorithm and apparatus to provide an optimized autonomous wire routing order for a robotic wiring process.

An embodiment of this disclosure can include a method to produce an optimum wire routing order comprising: defining a network of electrical wires as a set of nodes (wires) and edges (precedence); defining separation codes and routing direction, geometric location (STA, BL); defining crossover constraints and wire routing limitations; implementing wire weighting criteria; applying an optimization “greedy algorithm” to minimize conflicts or cyclic conditions between nodes (wires or constraints) by sequentially eliminating nodes and testing the network; retesting the network with the removed nodes reinserted; measuring relative efficiency of the network based on number of wires violating a constraint/total number of wires. An embodiment of this disclosure can include a robotic wire routing apparatus implementing the above method to produce an optimized wire routing sequence.

Embodiments of the present disclosure can, given a deadlocked partial ordering, remove the fewest number of nodes to achieve a non-deadlocked partial ordering. A non-deadlock partial ordering almost always has 1 or more feasible well orderings.

An embodiment of the present disclosure provides a method of sequencing wire assembly for autonomous routing, comprising: defining a weighted directed conflict graph representing a plurality of wires to be routed in a raceway, wherein the weighted directed conflict graph comprises a plurality of nodes defined by the plurality of wires and a plurality of edges defined by a set of routing precedents among the plurality of wires wherein a subsequent wire that is to be routed across a precedent wire within the raceway yields routing precedence to the precedent wire with regard to sequencing wire assembly denoted by one of the plurality of edges between the precedent wire and the subsequent wire that is directed from the precedent wire to the subsequent wire, increments an integer value of deg out=1 with regard to the precedent wire and increments an integer value deg in=1 with regard to the subsequent wire; then reducing the weighted directed conflict graph comprising removing and storing a node with an integer value of degree in=0 and/or an integer value of degree out=0; and then repeating the step of removing and storing until there are no nodes with an integer value of degree in=0 and/or an integer value of degree out=0; and then in response to the weighted directed conflict graph being deadlocked as defined by a presence of at least one cycle among a plurality of cyclic nodes wherein each of the plurality of cyclic nodes has an integer value of degree in>0 and an integer value of degree out>0, removing and storing a cyclic node to break the at least one cycle.

Another embodiment of the present disclosure provides an apparatus for sequencing wire assembly for autonomous routing, comprising: a computer system comprising a set of processors; and a computer readable storage medium having program code executable by the computer system for: defining a weighted directed conflict graph representing a plurality of wires to be routed in a raceway, wherein the weighted directed conflict graph comprises a plurality of nodes defined by the plurality of wires and a plurality of edges defined by a set of routing precedents among the plurality of wires wherein a subsequent wire that is to be routed across a precedent wire within the raceway yields routing precedence to the precedent wire with regard to sequencing wire assembly denoted by one of the plurality of edges between the precedent wire and the subsequent wire that is directed from the precedent wire to the subsequent wire, increments an integer value of deg out=1 with regard to the precedent wire and increments an integer value deg in=1 with regard to the subsequent wire; then reducing the weighted directed conflict graph comprising removing and storing a node with an integer value of degree in=0 and/or an integer value of degree out=0; and then repeating the step of removing and storing until there are no nodes with an integer value of degree in=0 and/or an integer value of degree out=0; and then in response to the weighted directed conflict graph being deadlocked as defined by a presence of at least one cycle among a plurality of cyclic nodes wherein each of the plurality of cyclic nodes has an integer value of degree in>0 and an integer value of degree out>0, removing and storing a cyclic node to break the at least one cycle.

Another embodiment of the present disclosure provides a computer program product for sequencing wire assembly for autonomous routing, the computer program product comprising a computer readable storage medium having program code embodied therewith, the program code executable for defining a weighted directed conflict graph representing a plurality of wires to be routed in a raceway, wherein the weighted directed conflict graph comprises a plurality of nodes defined by the plurality of wires and a plurality of edges defined by a set of routing precedents among the plurality of wires wherein a subsequent wire that is to be routed across a precedent wire within the raceway yields routing precedence to the precedent wire with regard to sequencing wire assembly denoted by one of the plurality of edges between the precedent wire and the subsequent wire that is directed from the precedent wire to the subsequent wire, increments an integer value of deg out=1 with regard to the precedent wire and increments an integer value deg in=1 with regard to the subsequent wire; then reducing the weighted directed conflict graph comprising removing and storing a node with an integer value of degree in=0 and/or an integer value of degree out=0; and then repeating the step of removing and storing until there are no nodes with an integer value of degree in=0 and/or an integer value of degree out=0; and then in response to the weighted directed conflict graph being deadlocked as defined by a presence of at least one cycle among a plurality of cyclic nodes wherein each of the plurality of cyclic nodes has an integer value of degree in>0 and an integer value of degree out>0, removing and storing a cyclic node to break the at least one cycle.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is an illustration of a block diagram of an apparatus for sequencing wire assembly for autonomous routing in accordance with an illustrative embodiment;

FIG. 2 is an illustration of a wire assembly for a raceway or conduit in accordance with an illustrative embodiment;

FIG. 3 is an illustration of a graph with selected features shown as 2 dimensional schema in accordance with an illustrative embodiment;

FIGS. 4A-4D are illustrations of graphs with some features shown as 2 dimensional schema in accordance with illustrative embodiments;

FIG. 5 is an illustration of a flowchart of a process for problem data preparation in accordance with an illustrative embodiment;

FIGS. 6A-6B are illustrations of a flowchart of a process for solving a deadlocked partial ordering in accordance with an illustrative embodiment;

FIG. 7 is an illustration of a flowchart of a generic process to begin solving a deadlock partial ordering in accordance with an illustrative embodiment;

FIG. 8 is an illustration of a flowchart of an optional sub-process for solving a deadlock partial ordering in accordance with an illustrative embodiment;

FIG. 9 is an illustration of a flowchart of an optional sub-process for solving a deadlock partial ordering in accordance with an illustrative embodiment;

FIG. 10 is an illustration of a flowchart of an optional sub-process for solving a deadlock partial ordering in accordance with an illustrative embodiment;

FIG. 11 is an illustration of a flowchart of an optional sub-process for solving a deadlock partial ordering in accordance with an illustrative embodiment;

FIG. 12 is an illustration of a flowchart of an optional sub-process for solving a deadlock partial ordering in accordance with an illustrative embodiment;

FIG. 13 is an illustration of a flowchart of an optional sub-process for solving a deadlock partial ordering in accordance with an illustrative embodiment;

FIG. 14 is an illustration of a flowchart of an optional sub-process for solving a deadlock partial ordering in accordance with an illustrative embodiment;

FIG. 15 is an illustration of an aircraft manufacturing and service method in a form of a block diagram in accordance with an illustrative embodiment; and

FIG. 16 is an illustration of an aircraft in the form of a block diagram in which an illustrative embodiment may be implemented.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well-known materials, techniques, components and equipment are omitted so as not to unnecessarily obscure the embodiments of the present disclosure in detail. It should be understood, however, that the detailed description and the specific examples are given by way of illustration only and not by way of limitation. Various substitutions, modifications, additions and/or rearrangements within the scope of the underlying inventive concept will become apparent to those skilled in the art from this disclosure.

The disclosure of this application is technically related to co-pending U.S. Ser. No. 18/634,337 (attorney docket number 23-1655-US-NP), filed Apr. 12, 2024, the entire contents of which are hereby expressly incorporated herein by reference for all purposes. U.S. Ser. No. 18/634,337 is incorporated herein by reference because it discloses wire assembly machines, systems, and methods for assembling electrical raceway modules.

Embodiments of this disclosure can include solving raceway wire routing sequencing problems and/or optimizing raceway wire routing sequencing solutions. Embodiments of this disclosure can include executing a set of steps to solve raceway wire routing sequencing problems and/or optimize raceway wire routing sequencing solutions. Embodiments of this disclosure can include physically routing a set of wires through an electrical raceway optionally using a wire assembly machine. Embodiments of this disclosure can include physically assembling electrical raceway modules optionally using robotics. Embodiments of this disclosure can include controlling solutions, optimizations, routings and/or assemblies. Embodiments of this disclosure can complete solutions, optimizations, routings and/or assemblies in seconds or minutes that would require an inordinate amount of time using mental steps (e.g. more than an adult lifetime of work time) even with paper and pencil.

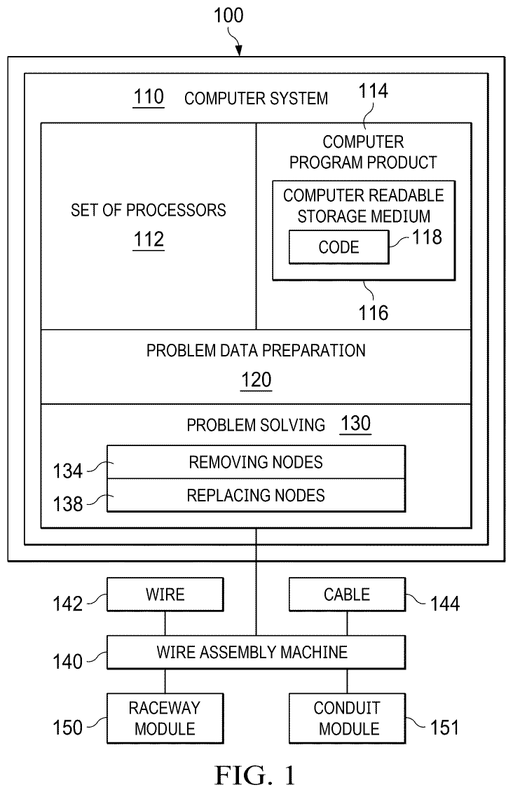

Turning now to FIG. 1, an illustration of a block diagram of an apparatus 100 for sequencing wire assembly for autonomous routing is shown. Apparatus 100 includes computer system 110. Computer system 110 includes a set of processors 112. Set of processors 112 is coupled to a computer program product 114. Computer program product 114 includes a computer readable storage medium 116. The computer readable storage medium 116 includes code 118.

Set of processors 112 is coupled to block 120. Problem data preparation 120 implements problem data preparation. Problem data preparation 120 is coupled to problem solving 130. Problem solving 130 implements problem solving. Problem solving 130 includes removing nodes 134 which implements removing nodes. Problem solving 130 also includes replacing nodes 138 which implements replacing nodes.

Problem solving 130 is coupled to wire assembly machine 140. Wire assembly machine 140 is coupled to a source of wire 142. Wire assembly machine 140 is also coupled to a source of cable 144. Wire assembly machine 140 operates to assemble aircraft electrical system raceway module 150. Alternatively, wire assembly machine 140 can operate to assemble aircraft electrical system conduit module 151.

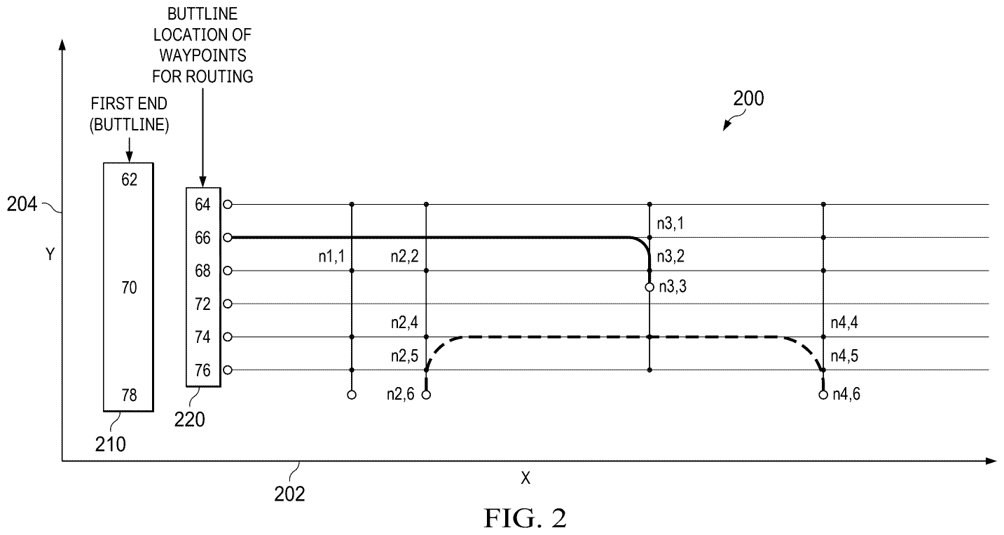

Referring to FIG. 2, an illustration is shown of a wire assembly 200 for installation in aircraft electrical system raceway module 150 or in aircraft electrical system conduit module 151 of FIG. 1. Wire assembly 200 defines an X axis 202 and a Y axis 204. Wire assembly 200 includes a first end 210. First end 210 can be termed a buttline. Wire assembly 200 defines plurality of waypoints for routing 220.

Embodiments of this disclosure can include assisting autonomous routing by generating routing order(s) using location data input for algorithmic sequencing. An objective of embodiments of this disclosure is to produce a routing sequence that satisfies the ‘crossover constraint’ needed for autonomous routing with a minimal number of wires slated for manual routing. This routing sequence should account for separation code and routing direction as provided by the initial data. At present, the station locations (x-direction) of the wires in the provided data set may be consolidated within a 10-unit span, and the buttline locations (y-locations) are adjusted based on initial routing direction with three possibilities (outboard=78, inboard=62, in-line=70). The separation code requirement will be followed by assigning a distinct y-location to each separation code.

In these embodiments, all data will be read as input and used to algorithmically determine a routing order that satisfies the ‘crossover constraint’ and identifies any wires that cannot be routed autonomously. It is worth noting that the final set of wires slated for manual routing currently is just one possible subset of the graph and it is possible that a different subset of lower cost could be found (i.e., optimality has not been proved).

For this problem, the wires can additionally be weighted based on some given criteria; the use of these criteria should likely impact routing order and specific wire groups or types selected for removal. These criteria can include the wire weight, the length of the wire, the wire diameter or number of conductors, and any effect of a top-down routing approach for certain wires. The inclusion of these criteria can provide additional insight that may inform or influence upstream or downstream contributors.

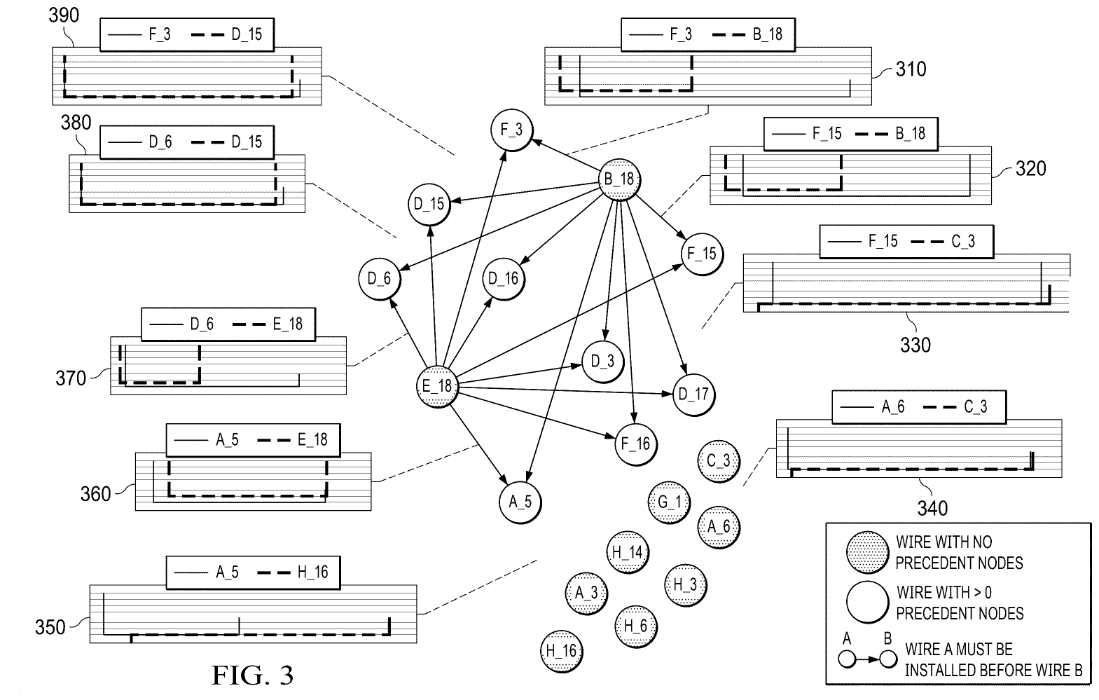

Referring to FIG. 3, an illustration of a graph with selected features shown as 2 dimensional schema is shown. Each wire is represented by a node. Wiring assembly precedence is represented by a directed edge (arrow) that is directed from a wire (node) that needs to be installed first to a wire (node) that needs to be installed second. In this graph, wires (nodes) with no precedent wires (nodes) are labeled H_16, A_3, H_14, G_1, C_3, H_6, H_3, and A_6. In this graph, wires with >0 precedent nodes are labeled A_5, F_16, D_17, F_15, B_18, F_3, D_15, D_6, E_18, D_16, and D_3. The spatial relationship between F_3 and B_18 is shown by first schema 310. The spatial relationship between F_15 and B_18 is shown by second schema 320. The spatial relationship between F_15 and C_3 is shown by third schema 330. The spatial relationship between A_6 and C_3 is shown by fourth schema 340. The spatial relationship between A_5 and H_16 is shown by fifth schema 350. The spatial relationship between A_5 and E_18 is shown by sixth schema 360. The spatial relationship between D_6 and E_18 is shown by seventh schema 370. The spatial relationship between D_6 and D_15 is shown by eighth schema 380. The spatial relationship between F_3 and D_15 is shown by ninth schema 390.

The graph includes directed edges to signify an order of precedence in routing between two nodes, if any. Once the full network has been formed, all nodes with degreeᵢₙ=0 or degreeₒᵤₜ=0 will be recursively removed from the graph (the degree measure is referencing the edges that the node has either pointing to or away from itself, meaning that a node with no edges pointing to other nodes will not have to be routed before other nodes, and a node with no edges pointing to itself does not require any other nodes to be routed before it). Then, the resulting graph will be considered. Any nodes not part of a cycle with degreeᵢₙ≥1 or degreeₒᵤₜ≥1 along with any corresponding nodes will be analyzed to further determine a routing order. The graph will be recursively reduced by removing nodes with degreeᵢₙ=0 or degreeₒᵤₜ=0 until the graph consists entirely of cycles. The removed nodes are added to a deleted graph.

Upon completion of these steps, the remaining nodes in the reduced graph will each be associated with a cycle and therefore cannot be easily removed to determine an appropriate routing order. Therefore, each cycle will need to be found and broken in an optimal manner. An algorithm to find cycles (a ‘cycle-finder’) is used and each node in a given cycle is identified. Any nodes that repeatedly occur in cycles will be removed from the graph for computational efficiency and can be re-added and revisited to determine overall optimality of the solution. Once each cycle in the graph is broken, a complete routing order can be produced. Subsequently, the removed nodes are then retested to ensure that they are the most cost-effective nodes to remove such that all cycles in the graph are broken. This approach can use mixed-integer linear programming and can reasonably approach optimality while retaining computational efficiency. The weighting of wires may also be considered, with respect to wire weight, the length of the wire, the wire diameter or number of conductors, and the effect of a top-down routing approach for certain wires.

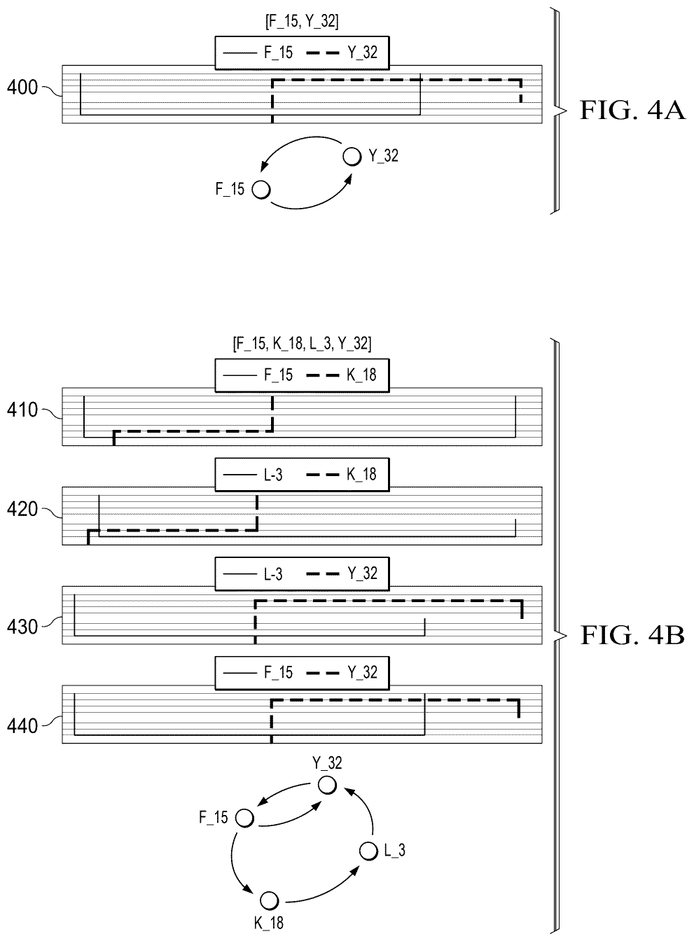

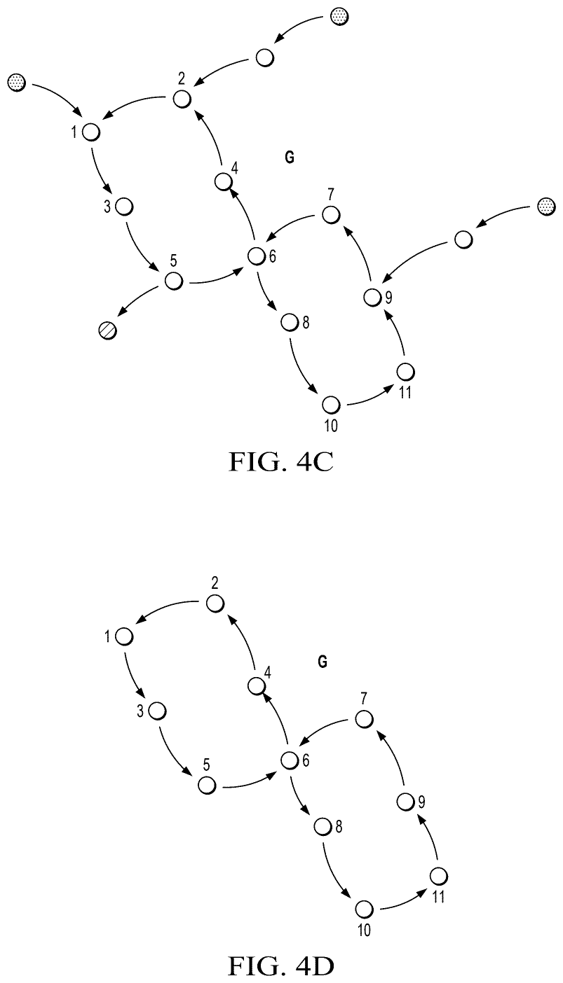

Referring to FIGS. 4A-4D, illustrations of graphs with selected features shown as 2 dimensional schema are shown. Referring to FIG. 4A, the cycle between F_15 and Y_32 represents a conflict. They cannot both be autonomously routed, and one needs to be segregated for manual routing. The spatial relationship between F_15 and Y_32 is shown by tenth schema 400. Referring to FIG. 4B, there are 2 cycles. Removing either F_15 or Y_32 from the graph (for manual routing) will break both cycles. The spatial relationship between F_15 and K_18 is shown by eleventh schema 410. The spatial relationship between L_3 and K_18 is shown by twelfth schema 420. The spatial relationship between L_3 and Y_32 is shown by thirteenth schema 430. The spatial relationship between F_15 and Y_32 is shown by fourteenth schema 440. Referring to FIGS. 4C-4D, reducing the directed conflict graph in FIG. 4C to the directed conflict graph in FIG. 4D can be effected by removing and storing the nodes with an integer value of degree in=0 and/or an integer value of degree out=0; and then repeating the step of removing and storing until there are no nodes with an integer value of degree in=0 and/or an integer value of degree out=0. Referring to FIG. 4D, there are three cycles in this diagram. Removing the center node breaks them all.

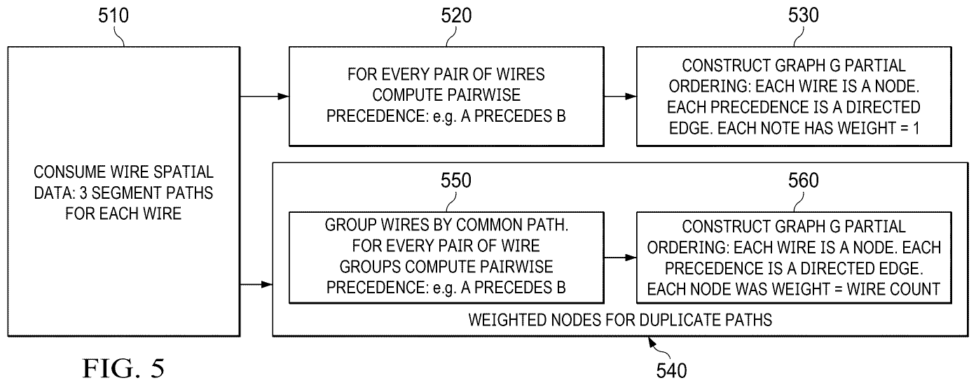

Referring to FIG. 5, a process for problem data preparation is shown. Block 510 includes a step to consume wire spatial data. In this embodiment, there are three segment paths for each wire. Block 520 includes a step where for every pair of wires pairwise precedence is computed. For example, in this embodiment, A precedes B. Block 530 includes a step of constructing a graph G. This step includes partial ordering. In the graph each wire is a node. In the graph, each precedence is a directed edge. In this embodiment, each node has a weight of 1. Block 540 is an alternative embodiment where at least some of the nodes have a weight other than 1. Block 540 also includes 2 blocks that are similar to block 520 and block 530. Block 550 includes a step that groups wires by common path. For every pair of wire groups, compute pairwise precedence. Again, A precedes B. Block 560 includes a step of constructing graph G with partial ordering. Each wire is a node. Each precedence is a directed edge. Each node has a weight equivalent to a wire count.

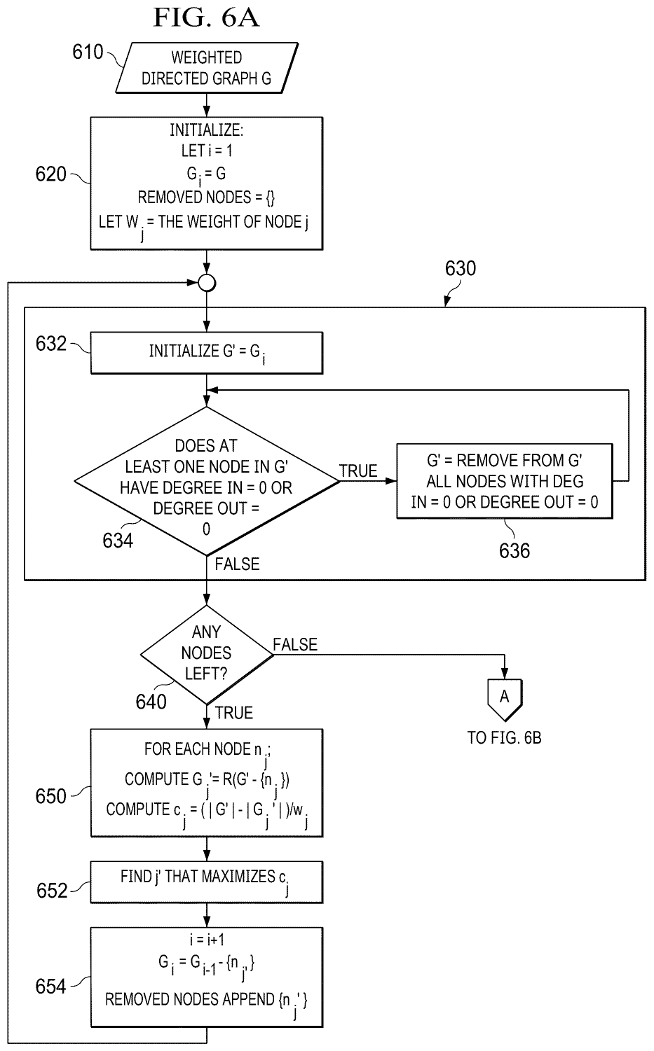

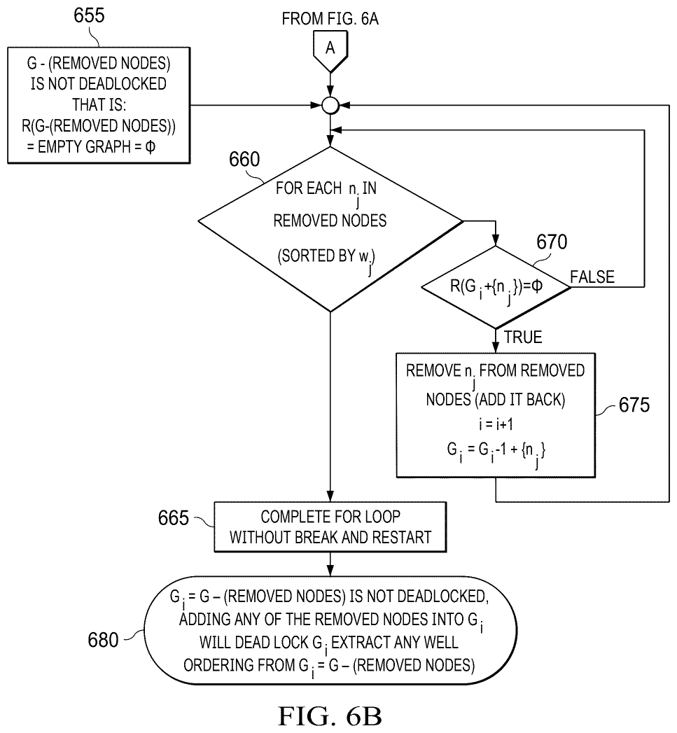

Referring to FIGS. 6A-6B, a detailed process for sequencing wire assembly for autonomous routing is shown. The process solves the problem of given a deadlocked partial ordering, removing the fewest number of nodes to achieve a non-deadlocked partial ordering. The reason for this is a non-deadlocked partial ordering always has one or more feasible well orderings.

The following definitions serve to facilitate a description of FIGS. 6A-6B:
G: The original conflict graph
Gᵢ (G₁, G₂, G₃, etc.): The graphs constructed as nodes are added or removed one at a time. In general, Gᵢ had one more or one less node than Gᵢ₋₁ and both have all relevant edges from G. Edge removal is always a consequence of Node removal
i: The index used as new graphs are made.
j: The index used when considering all nodes of a graph.
Reduced graph R (G): Produced algorithmically in FIGS. 6A-6B is the subgraph of G created by removing all nodes that are not part of one or more cycles. Every node in Gᵢ′ is a part of a cycle in both Gᵢ′ and Gᵢ. Every node in Gᵢ that is not part of any cycle is not in Gᵢ′.
G′: A temporary graph that undergoes heavy node and edge removal as I reduce any
Gᵢ to Gᵢ
Gᵢ: Gᵢ's reduced graph.
wⱼ: A weight on the node j (assigned outside the algorithm, for all nodes in G) that can be adjusted so that certain wires are preferred to be in the final acyclic graph.
cⱼ: A cost function that can be evaluated for any node j in a graph. The goal is to balance the value of the wire and its contribution to the cycles in the graph.
nⱼ: The j^{th} node in some graph.
Φ: The empty graph. For example, if a graph P is completely acyclic, R(G)=Φ

Still referring to FIGS. 6A-6B, block 610 includes defining a weighted direct graph G. Block 620 includes initializing to let i=1, Gᵢ=G, removed nodes={ }, and assigning weights (e.g. importance) to the nodes. Block 630 includes defining R(G). Block 632 includes initializing G′=Gᵢ. Block 634 includes a decision of whether at least one node in G′ has degree in=0 or degree out=0. Block 636 includes removing from G′ all nodes with deg in=0 or degree out=0. Block 640 includes a decision of whether there are any nodes remaining. When there are nodes remaining, block 650 includes calculations for each node. Block 652 includes finding j′ that maximizes cᵢ. Block 654 includes further calculations and a return to block 630.

In response to there being no nodes remaining at block 640, blocks 655, 660, 665, 670, 675 and 680 replace the removed nodes sorted by weight that can be replace without causing dead lock. An embodiment of this disclosure can include an optimization algorithm that can be termed a “greedy heuristic.” The following is an example of such an optimization algorithm.

$$Let {g}^{:} = r ( g )$$

While g′ is non-empty:
   For all nodes i in g′, find I that maximizes the ratio (lg′I−lr(D(g′,i))l)/wᵢ
      where Wᵢ is the weight of node i
      This is the ratio of benefit to cost in removing node i.
      Literally ‘bang for your buck’. bang/buck
   If more than one node maximizes this ratio:
      Identity the node that maximizes this ratio that has maximum total
      degree d(G,i)
Remove the node identified.
Tally that node weight as a cost.
Collect i in list_of_removed_nodes.

$$Let {g}^{′} = r ( D ( {g}^{′} , i ) )$$

Test that removed nodes could be added back:
   Put them back in (one at a time) and see if
      there are cycles and w
      whether they are the identified node in the above algorithm.
   If they can be added back, it just means they were identified early and subsequent nodes removed killed their cycles.
   Put the most valuable one (wᵢ) that can be added back in and repeat until none can be added back

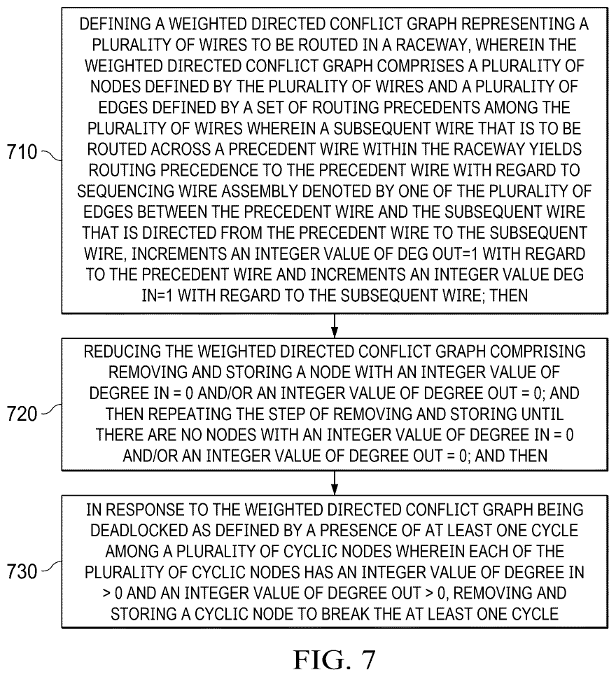

Referring to FIG. 7, a generic process for sequencing wire assembly for autonomous routing is shown. Block 710 includes defining a weighted directed conflict graph representing a plurality of wires to be routed in a raceway, wherein the weighted directed conflict graph comprises a plurality of nodes defined by the plurality of wires and a plurality of edges defined by a set of routing precedents among the plurality of wires wherein a subsequent wire that is to be routed across a precedent wire within the raceway yields routing precedence to the precedent wire with regard to sequencing wire assembly denoted by one of the plurality of edges between the precedent wire and the subsequent wire that is directed from the precedent wire to the subsequent wire, increments an integer value of deg out=1 with regard to the precedent wire and increments an integer value deg in=1 with regard to the subsequent wire. Block 720 includes reducing the weighted directed conflict graph comprising removing and storing a node with an integer value of degree in=0 and/or an integer value of degree out=0; and then repeating the step of removing and storing until there are no nodes with an integer value of degree in=0 and/or an integer value of degree out=0. Block 730 includes in response to the weighted directed conflict graph being deadlocked as defined by a presence of at least one cycle among a plurality of cyclic nodes wherein each of the plurality of cyclic nodes has an integer value of degree in>0 and an integer value of degree out>0, removing and storing a cyclic node to break the at least one cycle.

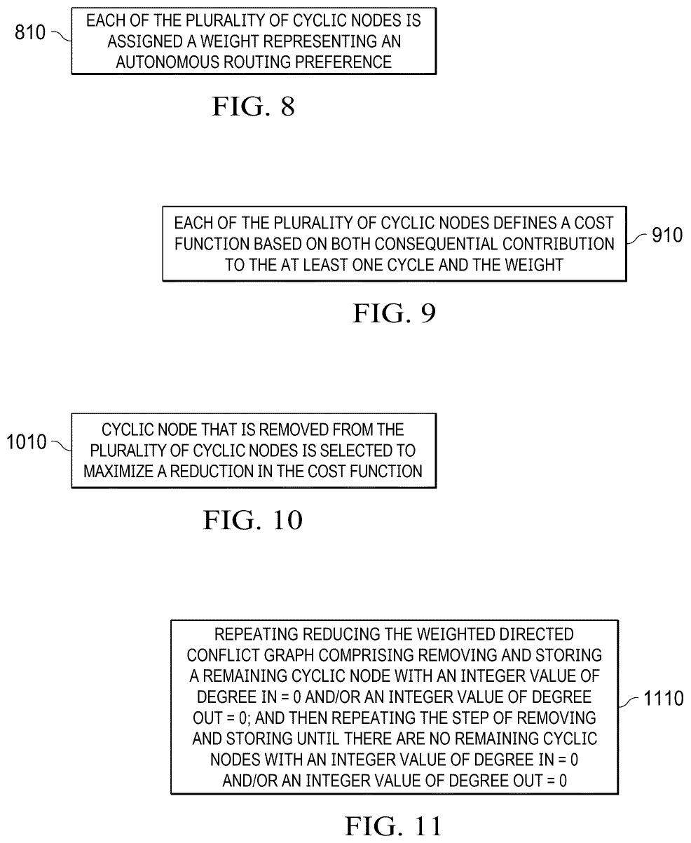

Referring to FIG. 8, an optional sub-process for sequencing wire assembly for autonomous routing is shown. Block 810 includes wherein each of the plurality of cyclic nodes is assigned a weight representing an autonomous routing preference.

Referring to FIG. 9, an optional sub-process for sequencing wire assembly for autonomous routing is shown. Block 910 includes wherein each of the plurality of cyclic nodes defines a cost function based on both consequential contribution to the at least one cycle and the weight.

Referring to FIG. 10, an optional sub-process for sequencing wire assembly for autonomous routing is shown. Block 1010 includes wherein the cyclic node that is removed from the plurality of cyclic nodes is selected to maximize a reduction in the cost function.

Referring to FIG. 11, an optional sub-process for sequencing wire assembly for autonomous routing is shown. Block 1110 includes repeating reducing the weighted directed conflict graph comprising removing and storing a remaining cyclic node with an integer value of degree in=0 and/or an integer value of degree out=0. Block 1120 includes repeating the step of removing and storing until there are no remaining cyclic nodes with an integer value of degree in=0 and/or an integer value of degree out=0.

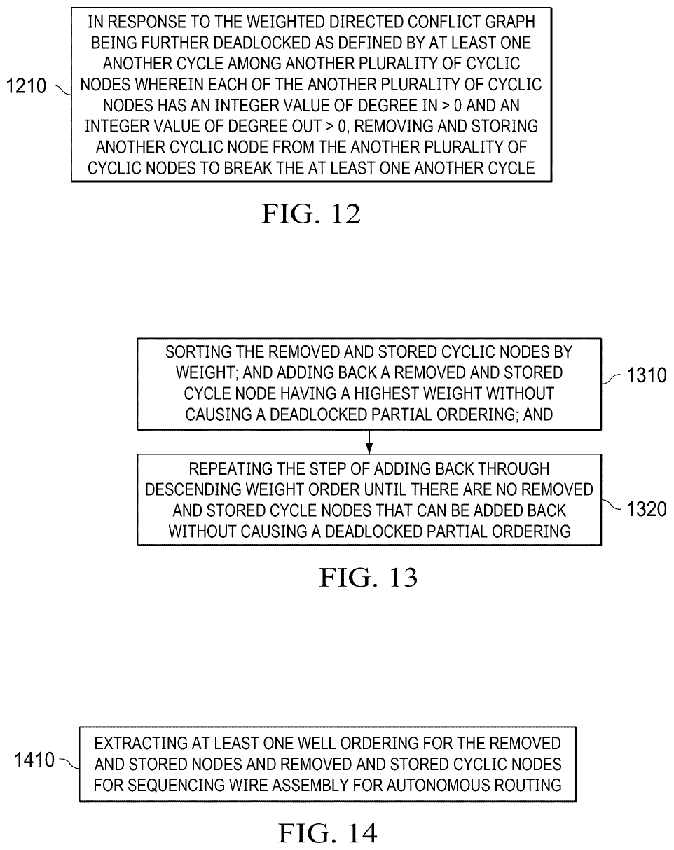

Referring to FIG. 12, an optional sub-process for sequencing wire assembly for autonomous routing is shown. Block 1210 includes in response to the weighted directed conflict graph being further deadlocked as defined by at least one another cycle among another plurality of cyclic nodes wherein each of the another plurality of cyclic nodes has an integer value of degree in>0 and an integer value of degree out>0, removing and storing another cyclic node from the another plurality of cyclic nodes to break the at least one another cycle.

Referring to FIG. 13, an optional sub-process for sequencing wire assembly for autonomous routing is shown. Block 1310 includes sorting the removed and stored cyclic nodes by weight; and adding back a removed and stored cycle node having a highest weight without causing a deadlocked partial ordering. Block 1320 includes repeating the step of adding back through descending weight order until there are no removed and stored cycle nodes that can be added back without causing a deadlocked partial ordering.

Referring to FIG. 14, an optional sub-process for sequencing wire assembly for autonomous routing is shown. Block 1410 includes extracting at least one well ordering for the removed and stored nodes and removed and stored cyclic nodes for sequencing wire assembly for autonomous routing.

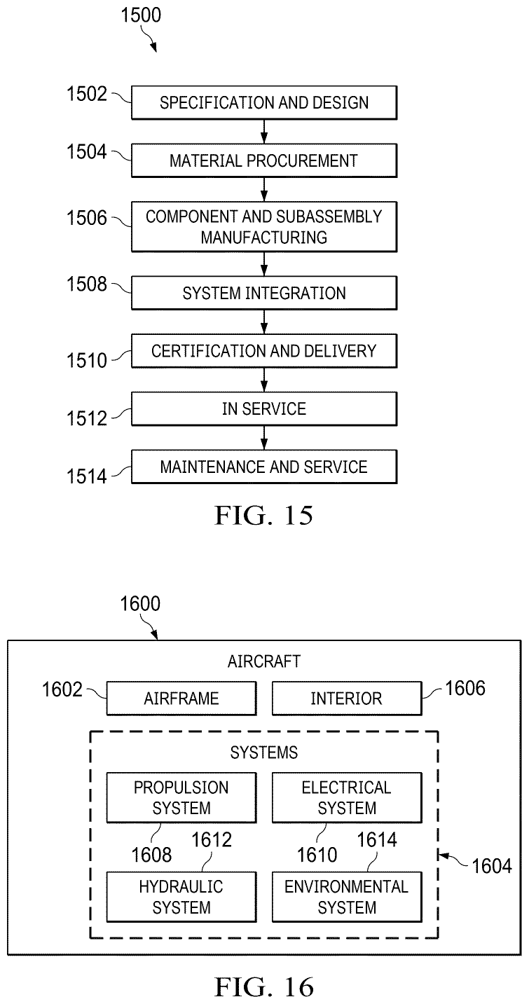

Illustrative embodiments of the present disclosure may be described in the context of aircraft manufacturing and service method 1500 as shown in FIG. 15 and aircraft 1600 as shown in FIG. 16. Turning first to FIG. 15, an illustration of an aircraft manufacturing and service method in the form of a block diagram is depicted in accordance with an illustrative embodiment. During pre-production, aircraft manufacturing and service method 1500 may include specification and design 1502 of aircraft 1600 in FIG. 16 and material procurement 1504.

During production, component and subassembly manufacturing 1506 and system integration 1508 of aircraft 1600 takes place. Thereafter, aircraft 1600 may go through certification and delivery 1510 in order to be placed in service 1512. While in service 1512 by a customer, aircraft 1600 is scheduled for routine maintenance and service 1514, which may include modification, reconfiguration, refurbishment, or other maintenance and service.

Each of the processes of aircraft manufacturing and service method 1500 may be performed or carried out by a system integrator, a third party, and/or an operator. In these examples, the operator may be a customer. For the purposes of this description, a system integrator may include, without limitation, any number of aircraft manufacturers and major-system subcontractors; a third party may include, without limitation, any number of vendors, subcontractors, and suppliers; and an operator may be an airline, a leasing company, a military entity, a service organization, and so on.

With reference now to FIG. 16, an illustration of an aircraft in a form of a block diagram is depicted in which an illustrative embodiment may be implemented. In this example, aircraft 1600 is produced by aircraft manufacturing and service method 1500 of FIG. 15 and may include airframe 1602 with plurality of systems 1604 and interior 1606. Examples of systems 1604 include one or more of propulsion system 1608, electrical system 1610, hydraulic system 1612, and environmental system 1614. Any number of other systems may be included.

Apparatuses and methods embodied herein may be employed during at least one of the stages of aircraft manufacturing and service method 1500. One or more illustrative embodiments may be manufactured or used during at least one of component and subassembly manufacturing 1506, system integration 1508, in service 1512, or maintenance and service 1514 of FIG. 15.

The description of the different illustrative embodiments has been presented for purposes of illustration and description and is not intended to be exhaustive or limited to the embodiments in the form disclosed. Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A method of sequencing wire assembly for autonomous routing, comprising:
defining a weighted directed conflict graph representing a plurality of wires to be routed in a raceway, wherein the weighted directed conflict graph comprises a plurality of nodes defined by the plurality of wires and a plurality of edges defined by a set of routing precedents among the plurality of wires wherein a subsequent wire that is to be routed across a precedent wire within the raceway yields routing precedence to the precedent wire with regard to sequencing wire assembly denoted by one of the plurality of edges between the precedent wire and the subsequent wire that is directed from the precedent wire to the subsequent wire, increments an integer value of deg out=1 with regard to the precedent wire and increments an integer value deg in=1 with regard to the subsequent wire; then
reducing the weighted directed conflict graph comprising:
removing and storing a node with an integer value of degree in=0 and/or an integer value of degree out=0; and then
repeating the step of removing and storing until there are no nodes with an integer value of degree in=0 and/or an integer value of degree out=0; and then
in response to the weighted directed conflict graph being deadlocked as defined by a presence of at least one cycle among a plurality of cyclic nodes wherein each of the plurality of cyclic nodes has an integer value of degree in>0 and an integer value of degree out>0, removing and storing a cyclic node to break the at least one cycle.

2. The method of claim 1, wherein each of the plurality of cyclic nodes is assigned a weight representing an autonomous routing preference.

3. The method of claim 2, wherein each of the plurality of cyclic nodes defines a cost function based on both consequential contribution to the at least one cycle and the weight.

4. The method of claim 3, wherein the cyclic node that is removed from the plurality of cyclic nodes is selected to maximize a reduction in the cost function.

5. The method of claim 4, further comprising repeating reducing the weighted directed conflict graph comprising:
removing and storing a remaining cyclic node with an integer value of degree in=0 and/or an integer value of degree out=0; and then
repeating the step of removing and storing until there are no remaining cyclic nodes with an integer value of degree in=0 and/or an integer value of degree out=0.

6. The method of claim 5, further comprising:
in response to the weighted directed conflict graph being further deadlocked as defined by at least one another cycle among another plurality of cyclic nodes wherein each of the another plurality of cyclic nodes has an integer value of degree in>0 and an integer value of degree out>0, removing and storing another cyclic node from the another plurality of cyclic nodes to break the at least one another cycle.

7. The method of claim 6, further comprising sorting the removed and stored cyclic nodes by weight; and adding back a removed and stored cycle node having a highest weight without causing a deadlocked partial ordering; and
repeating the step of adding back through descending weight order until there are no removed and stored cycle nodes that can be added back without causing a deadlocked partial ordering.

8. The method of claim 7, further comprising extracting at least one well ordering for the removed and stored nodes and removed and stored cyclic nodes for sequencing wire assembly for autonomous routing.

9. The method of claim 1, further comprising executing the steps of defining reducing, and removing and storing.

10. The method of claim 1, further comprising controlling the steps of defining reducing, and removing and storing.

11. The method of claim 1, further comprising routing at least a subset of the plurality of wires to be routed in the raceway using a wire assembly machine.

12. The method of claim 1, further comprising assembling a raceway module.

13. An aircraft electrical system raceway module comprising a plurality of wires autonomously routed using the method of claim 1.

14. An apparatus for sequencing wire assembly for autonomous routing, comprising:
a computer system comprising:
a set of processors; and
a computer readable storage medium having program code executable by the computer system for:
defining a weighted directed conflict graph representing a plurality of wires to be routed in a raceway, wherein the weighted directed conflict graph comprises a plurality of nodes defined by the plurality of wires and a plurality of edges defined by a set of routing precedents among the plurality of wires wherein a subsequent wire that is to be routed across a precedent wire within the raceway yields routing precedence to the precedent wire with regard to sequencing wire assembly denoted by one of the plurality of edges between the precedent wire and the subsequent wire that is directed from the precedent wire to the subsequent wire, increments an integer value of deg out=1 with regard to the precedent wire and increments an integer value deg in=1 with regard to the subsequent wire; then
reducing the weighted directed conflict graph comprising:
removing and storing a node with an integer value of degree in=0 and/or an integer value of degree out=0; and then
repeating the step of removing and storing until there are no nodes with an integer value of degree in=0 and/or an integer value of degree out=0; and then
in response to the weighted directed conflict graph being deadlocked as defined by a presence of at least one cycle among a plurality of cyclic nodes wherein each of the plurality of cyclic nodes has an integer value of degree in>0 and an integer value of degree out>0, removing and storing a cyclic node to break the at least one cycle.

15. The apparatus of claim 14, wherein each of the plurality of cyclic nodes is assigned a weight representing an autonomous routing preference.

16. The apparatus of claim 15, wherein each of the plurality of cyclic nodes defines a cost function based on both consequential contribution to the at least one cycle and the weight.

17. The apparatus of claim 16, wherein the cyclic node that is removed from the plurality of cyclic nodes is selected to maximize a reduction in the cost function.

18. The apparatus of claim 17, further comprising program code for:
repeating reducing the weighted directed conflict graph comprising:
removing and storing a remaining cyclic node with an integer value of degree in=0 and/or an integer value of degree out=0; and then
repeating the step of removing and storing until there are no remaining cyclic nodes with an integer value of degree in=0 and/or an integer value of degree out=0.

19. The apparatus of claim 18, further comprising program code for:
in response to the weighted directed conflict graph being further deadlocked as defined by at least one another cycle among another plurality of cyclic nodes wherein each of the another plurality of cyclic nodes has an integer value of degree in>0 and an integer value of degree out>0, removing and storing another cyclic node from the another plurality of cyclic nodes to break the at least one another cycle.

20. The apparatus of claim 19, further comprising program code for:
sorting the removed and stored cyclic nodes by weight; and adding back a removed and stored cycle node having a highest weight without causing a deadlocked partial ordering; and
repeating the step of adding back through descending weight order until there are no removed and stored cycle nodes that can be added back without causing a deadlocked partial ordering.

21. The apparatus of claim 20, further comprising program code for:
extracting at least one well ordering for the removed and stored nodes and removed and stored cyclic nodes for sequencing wire assembly for autonomous routing.

22. A machine for autonomous wire routing comprising the apparatus of claim 14.

23. A computer program product for sequencing wire assembly for autonomous routing, the computer program product comprising a computer readable storage medium having program code embodied therewith, the program code executable by a computer system for:
defining a weighted directed conflict graph representing a plurality of wires to be routed in a raceway, wherein the weighted directed conflict graph comprises a plurality of nodes defined by the plurality of wires and a plurality of edges defined by a set of routing precedents among the plurality of wires wherein a subsequent wire that is to be routed across a precedent wire within the raceway yields routing precedence to the precedent wire with regard to sequencing wire assembly denoted by one of the plurality of edges between the precedent wire and the subsequent wire that is directed from the precedent wire to the subsequent wire, increments an integer value of deg out=1 with regard to the precedent wire and increments an integer value deg in=1 with regard to the subsequent wire; then
reducing the weighted directed conflict graph comprising:
removing and storing a node with an integer value of degree in=0 and/or an integer value of degree out=0; and then
repeating the step of removing and storing until there are no nodes with an integer value of degree in=0 and/or an integer value of degree out=0; and then
in response to the weighted directed conflict graph being deadlocked as defined by a presence of at least one cycle among a plurality of cyclic nodes wherein each of the plurality of cyclic nodes has an integer value of degree in>0 and an integer value of degree out>0, removing and storing a cyclic node to break the at least one cycle.

24. The computer program product of claim 23, wherein each of the plurality of cyclic nodes is assigned a weight representing an autonomous routing preference.

25. The computer program product of claim 24, wherein each of the plurality of cyclic nodes defines a cost function based on both consequential contribution to the at least one cycle and the weight.

26. The computer program product of claim 25, wherein the cyclic node that is removed from the plurality of cyclic nodes is selected to maximize a reduction in the cost function.

27. The computer program product of claim 26, further comprising program code for:
repeating reducing the weighted directed conflict graph comprising:
removing and storing a remaining cyclic node with an integer value of degree in=0 and/or an integer value of degree out=0; and then
repeating the step of removing and storing until there are no remaining cyclic nodes with an integer value of degree in=0 and/or an integer value of degree out=0.

28. The computer program product of claim 27, further comprising program code for:
in response to the weighted directed conflict graph being further deadlocked as defined by at least one another cycle among another plurality of cyclic nodes wherein each of the another plurality of cyclic nodes has an integer value of degree in>0 and an integer value of degree out>0, removing and storing another cyclic node from the another plurality of cyclic nodes to break the at least one another cycle.

29. The computer program product of claim 28, further comprising program code for:
sorting the removed and stored cyclic nodes by weight; and adding back a removed and stored cycle node having a highest weight without causing a deadlocked partial ordering; and
repeating the step of adding back through descending weight order until there are no removed and stored cycle nodes that can be added back without causing a deadlocked partial ordering.

30. The computer program product of claim 29, further comprising program code for extracting at least one well ordering for the removed and stored nodes and removed and stored cyclic nodes for sequencing wire assembly for autonomous routing.

31. A computer system comprising the computer program product of claim 23.
